(19) United States
(12) Patent Application Publication
(10) Pub. No.: US 2023/0299025 A1
(43) Pub. Date: Sep. 21, 2023

(54) SEMICONDUCTOR DEVICE AND SEMICONDUCTOR MANUFACTURING APPARATUS

(71) Applicant: Kioxia Corporation, Tokyo (JP)

(72) Inventor: Yuji Setta, Kuwana Mie (JP)

(73) Assignee: Kioxia Corporation, Tokyo (JP)

(21) Appl. No.: 17/890,368

(22) Filed: Aug. 18, 2022

(30) Foreign Application Priority Data
Mar. 18, 2022 (JP) 2022-043594

(51) Int. Cl. H01L 23/00; H01L 23/58; H01L 21/02; G03F 7/20; H01L 27/105

(52) U.S. Cl. CPC H01L 24/05; H01L 23/585; H01L 21/02002; H01L 24/08; G03F 7/20; H01L 24/80; H01L 27/1052; H01L 2224/05647; H01L 2224/08145; H01L 2224/808

(57) ABSTRACT

A semiconductor device includes a first device; and a second device bonded to the first device. The first device includes a plurality of first metal pads provided above a semiconductor substrate with an approximately circular shape; a first circuit coupled to at least one of the plurality of the first metal pads; and a first metal ring provided along an outer circumference of the semiconductor substrate to surround the first circuit. The second device includes a plurality of second metal pads joined to the plurality of the first metal pads, respectively; a second circuit coupled to at least one of the plurality of the second metal pads; and a second metal ring joined to the first metal ring.

### CROSS-REFERENCE TO RELATED APPLICATION

This application is based upon and claims the benefit of priority from Japanese Patent Application No. 2022-043594, filed Mar. 18, 2022, the entire contents of which are incorporated herein by reference.

### FIELD

Embodiments described herein relate generally to a semiconductor device and a semiconductor manufacturing apparatus.

### BACKGROUND

Bonding processes are generally utilized for improving densification of semiconductor devices, effective usage of device areas, and so on. In the bonding process, for example, a semiconductor substrate having memory cells and a semiconductor substrate having peripheral circuits such as a CMOS are bonded together while respective metal pads are joined. A semiconductor device having substrates that are bonded by the bonding process may be insufficient in bonding strength of bonded parts at outer circumferential parts of the semiconductor substrates. This can cause problems such as separation between the semiconductor substrates and occurrence of defects in the semiconductor substrate in later processes. In this regard, it is desired to improve bonding properties at outer circumferential parts of semiconductor substrates and thereby enhance quality and manufacturing yield of semiconductor devices.

### DESCRIPTION OF THE DRAWINGS

FIG. 1 is a sectional view illustrating a semiconductor device of an embodiment.

FIG. 2 is a sectional view illustrating a final structure of the semiconductor device of the embodiment.

FIG. 3 is a plane view illustrating a device forming part of one of semiconductor substrates of the semiconductor device in FIG. 1.

FIG. 4 is an enlarged sectional view illustrating a part of the semiconductor device in FIG. 1.

FIG. 5 is an enlarged sectional view illustrating first and second metal rings of the semiconductor device in FIG. 4.

FIGS. 6A to 6G are sectional views illustrating a process of manufacturing the semiconductor device of the embodiment.

FIG. 7 is a plane view illustrating a semiconductor manufacturing apparatus used in the process of manufacturing the semiconductor device of the embodiment.

FIG. 8 is a front view of the semiconductor manufacturing apparatus illustrated in FIG. 7.

FIG. 9 is a sectional view illustrating a configuration example of a semiconductor chip that is manufactured by using the semiconductor device of the embodiment.

### DETAILED DESCRIPTION

In general, according to one embodiment, a semiconductor device includes a first device; and a second device bonded to the first device. The first device includes a plurality of first metal pads provided above a semiconductor substrate with an approximately circular shape; a first circuit coupled to at least one of the plurality of the first metal pads; and a first metal ring provided along an outer circumference of the semiconductor substrate to surround the first circuit. The second device includes a plurality of second metal pads joined to the plurality of the first metal pads, respectively; a second circuit coupled to at least one of the plurality of the second metal pads; and a second metal ring joined to the first metal ring.

Hereinafter, a semiconductor device and a semiconductor manufacturing apparatus of an embodiment will be described with reference to the drawings. It is noted that substantially the same elements are denoted by the same reference signs, and descriptions thereof may be partially omitted in each embodiment. The drawings are schematic illustrations, and relations between thickness and dimensions in a plane, ratios of thickness of elements, etc., may be different from those of actual elements. Unless otherwise noted, the phrase that shows a direction, such as an upper or lower direction, in the description, is a relative direction, assuming that a metal pad forming surface of a first semiconductor substrate is on an upper side. The direction may be different from an actual direction based on the direction of the gravitational acceleration.

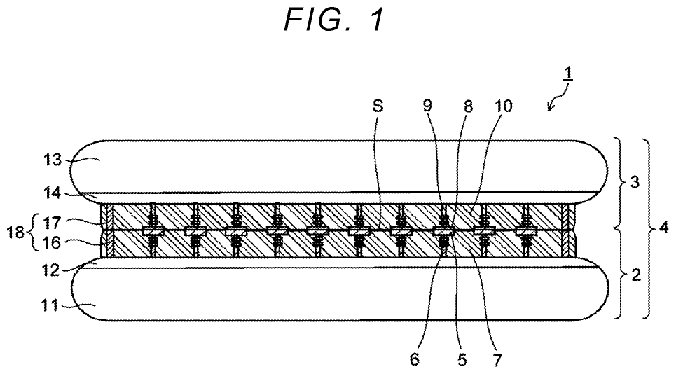

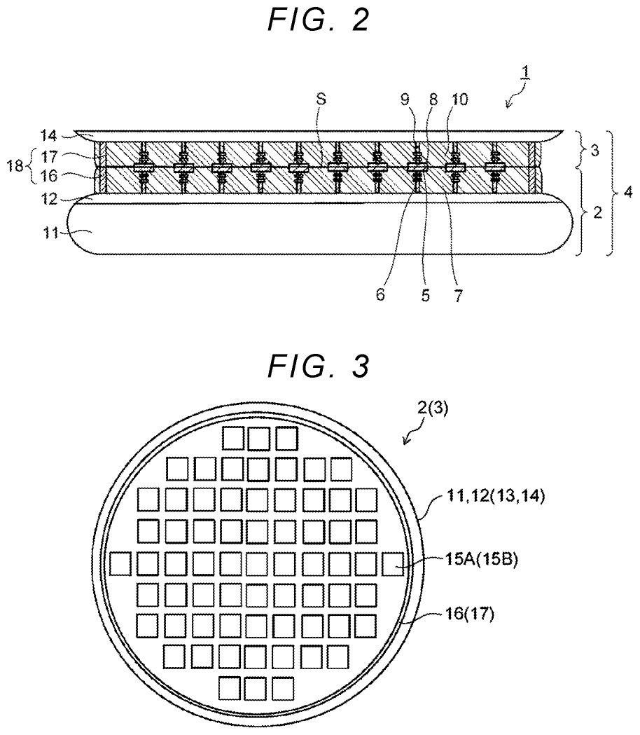

FIGS. 1 and 2 are sectional views illustrating a semiconductor device 1 of an embodiment. FIG. 3 is a plane view illustrating a device forming part of one of semiconductor substrates of the semiconductor device 1 of the embodiment. FIG. 1 illustrates the semiconductor device 1 in a prior stage of thinning one of two semiconductor substrates that constitute a bonded substrate, by back grinding or a chemical treatment. FIG. 2 illustrates the semiconductor device 1 in a post stage of thinning the one of the two semiconductor substrates by back grinding or a chemical treatment.

The semiconductor device 1 illustrated in FIG. 1 includes a first semiconductor substrate 2 and a second semiconductor substrate 3. The first and the second semiconductor substrates 2 and 3 are generally called “semiconductor wafers” having a circular (disc) shape. A semiconductor wafer may include a notch that is provided at an outer circumference, and therefore, the circular shape of the semiconductor wafer includes such a shape as having a notch as well as a perfect circle. That is, the shape of the semiconductor wafer can be an approximately circle, and the wafer shape is not limited to a perfect circle and includes such an approximately circular shape as having a notch. The first and the second semiconductor substrates 2 and 3 are bonded together and form a bonded substrate 4. In short, the semiconductor device 1 includes the bonded substrate 4. The reference sign “S” shows a bonded surface of the first and the second semiconductor substrates 2 and 3. The bonded surface “S” is illustrated for convenience of explanation, and a visually recognizable bonded interface may not exist due to integration of the first and the second semiconductor substrates 2 and 3. Nevertheless, the bonded state of the first and the second semiconductor substrates 2 and 3 can be recognized by analyzing a cross section of the bonded substrate 4.

The first semiconductor substrate 2 includes a plurality of first metal pads 5. The first metal pad 5 is connected to a first wiring layer 6. The first metal pads 5 and the first wiring layer 6 are embedded in a first insulating layer 7 that serves as an interlayer insulating film. The second semiconductor substrate 3 includes a plurality of second metal pads 8. The second metal pad 8 is connected to a second wiring layer 9. The second metal pads 8 and the second wiring layer 9 are embedded in a second insulating layer 10 that serves as an interlayer insulating film. Herein, a state of the first and the second metal pads 5 and 8 being respectively connected to the first and the second wiring layers 6 and 9 is illustrated. That is, FIG. 1 illustrates the first and the second metal pads 5 and 8 that are respectively connected to the first and the second wiring layers 6 and 9. As described later, one or a plurality of each of the first and the second metal pads 5 and 8 may be a dummy pad that is not connected to the wiring layer. In addition, each of the first and the second wiring layers 6 and 9 may include a via plug (described later).

The first semiconductor substrate 2 includes a first circuit region 12 that is provided with a first circuit (not illustrated). The first circuit includes peripheral circuits (not illustrated), for example, a transistor, such as a CMOS, and a passive element, and also includes a wiring layer connecting the peripheral circuits and at least one of the first metal pads 5. The first circuit region 12 is provided on a substrate part 11 of the first semiconductor substrate 2. The second semiconductor substrate 3 includes a second circuit region 14 that is provided with a second circuit (not illustrated). The second circuit includes, for example, a pixel array having a plurality of pixels of an image sensor, a memory cell array having a plurality of memory cells, a source line, a plurality of bit lines, and a wiring layer connected to at least one of the second metal pads 8. The second circuit region 14 is provided under a substrate part 13 of the second semiconductor substrate 3. The first semiconductor substrate 2 constitutes, for example, a control circuit chip, whereas the second semiconductor substrate 3 constitutes, for example, an array chip.

As illustrated in FIG. 2, the second semiconductor substrate 3 is thinned by performing back grinding or a chemical treatment on the bonded substrate 4 in such a manner that at least the second circuit region 14 remains. At the time of processing, it does not matter whether the substrate part 13 of the second semiconductor substrate 3 remains or not. In the semiconductor device 1 illustrated in FIG. 2, the first semiconductor substrate 2 having the first metal pads 5 and the first circuit region 12 is used as a first device forming part (or a first device). On the other hand, the second semiconductor substrate 3 having the second metal pads 8 and the second circuit region 14 but not having the substrate part 13 due to removal, in other words, the remaining part of the second semiconductor substrate 3 in which the substrate part 13 is removed, is used as a second device forming part (or a second device).

FIG. 3 is a plane view illustrating one of the semiconductor substrates (first semiconductor substrate 2 or second semiconductor substrate 3) before it is bonded to constitute the bonded substrate 4 of the semiconductor device 1. As illustrated in FIG. 3, the first semiconductor substrate 2 includes a plurality of chip regions 15A. Similarly, the second semiconductor substrate 3 includes a plurality of chip regions 15B. Although not illustrated in FIG. 3, each chip region 15A of the first semiconductor substrate 2 includes the first metal pads 5, the first wiring layer 6, and the first circuit having peripheral circuits, e.g., a transistor, such as a CMOS, and a passive element, and having a wiring layer and so on, as described above. Each chip region 15B of the second semiconductor substrate 3 includes the second metal pads 8, the second wiring layer 9, and the second circuit having a pixel array, a memory cell array, a wiring layer, and so on, as described above.

In more detail, the first and the second metal pads 5 and 8 are provided in such a manner as to be exposed to the surfaces of the chip regions 15A and 15B of the first and the second semiconductor substrates 2 and 3, respectively. In the chip regions 15A and 15B, the first and the second metal pads 5 and 8 are joined to each other, and the surrounding first and second insulating layers 7 and 10 are joined to each other. These elements bond the plurality of the first chip regions 15A and the plurality of the second chip regions 15B to each other. These plurality of the chip regions 15A and 15B provide a plurality of semiconductor chips after the bonded substrate 4 is diced.

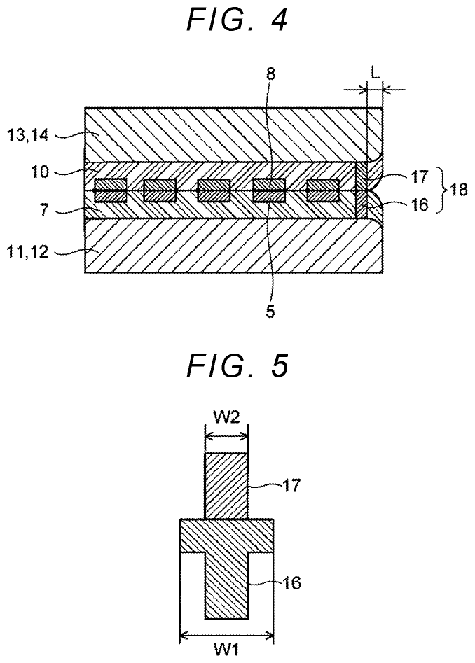

Moreover, first and second metal rings 16 and 17 are respectively provided in outer circumferential regions of the first and the second semiconductor substrates 2 and 3, along the outer circumferences thereof, so as to surround the first circuits in the first circuit region 12 (the second circuits in the second circuit region 14) in a top view. The first and the second metal rings 16 and 17 are respectively provided along the outer circumferences of the first and the second semiconductor substrates 2 and 3, so as to surround chip forming regions having the plurality of the chip regions 15A and 15B. The first and the second metal rings 16 and 17 may have a structure of stacking a plurality of ring-shaped metal patterns. In this case, the ring-shaped metal patterns are formed by repeatedly performing a process of exposing a plurality of wiring layers so as to generate a ring-shaped pattern and a process of embedding a metal material thereinto (which are described later). FIGS. 1 and 4 (described later) illustrate the first and the second metal rings 16 and 17. The first and the second metal rings 16 and 17 are formed by staking a plurality of ring-shaped metal patterns in a direction in which the first and the second semiconductor substrates 2 and 3 face each other (Z direction which will be described later). The first and the second metal rings 16 and 17 are respectively extended in the Z direction from the facing surfaces of the first and the second semiconductor substrates 2 and 3 (surfaces of the first and the second insulating layers 7 and 10) to the first and the second circuit regions 12 and 14.

The pair of the first and the second metal pads 5 and 8 and the pair of the first and the second metal rings 16 and 17 contribute to bonding of the first and the second semiconductor substrates 2 and 3. The pair of the first and the second insulating layers 7 and 10 also contributes to bonding of the first and the second semiconductor substrates 2 and 3. Each of the first and the second insulating layers 7 and 10 uses an inorganic insulating material such as silicon oxide (SiO), silicon nitride (SiN), silicon carbide (SiC), silicon oxynitride (SiON), or nitrogen-containing silicon carbide (SiCN), but they may be made of another insulating material. The first and the second insulating layers 7 and 10 may have a structure of stacking one or multiple kinds of materials. Each of the first and the second metal pads 5 and 8 and the first and the second metal rings 16 and 17 uses a metal material having a coefficient of thermal expansion higher than that of the inorganic insulating material used in the first and the second insulating layers 7 and 10, for example, they use copper, copper alloy, or the like, but they may be made of another metal material.

The pair of the surface of the first metal pad 5, which is exposed to the bonding surface of the first semiconductor substrate 2, and the surface of the second metal pad 8, which is exposed to the bonding surface of the second semiconductor substrate 3, and the pair of the surface of the first metal ring 16 and the surface of the second metal ring 17, are directly joined to each other by intermetallic element diffusion, van der Waals force, metallic bonding due to volume expansion (thermal expansion), or the like. At the same time, the surface of the first insulating layer 7, which is exposed to the bonding surface of the first semiconductor substrate 2, and the surface of the second insulating layer 10, which is exposed to the bonding surface of the second semiconductor substrate 3, are directly joined to each other by element diffusion between insulators, van der Waals force, chemical reaction such as dehydration condensation or polymerization, or the like. These elements bond together the first and the second semiconductor substrates 2 and 3.

For example, in the case of using SiO₂ film or the like as the first and the second insulating layers 7 and 10, the surfaces of the first and the second insulating layers 7 and 10 are activated by nitrogen (N₂) plasma or the like. Next, the surfaces of the first and the second insulating layers 7 and 10 are cleaned with deionized water or the like, and an OH group is added to these surfaces (Si—OH bonding). Subsequently, the first and the second semiconductor substrates 2 and 3 are positioned and stacked. During this process, they are bonded together by hydrogen bonding between the surface of the first insulating layer 7 and the surface of the second insulating layer 10. Thereafter, they are subjected to an anneal treatment, for example, at a temperature of 300 to 400° C. for approximately 1 hour. Thus, the pair of the copper pads and the pair of the copper rings are metal-joined to each other by thermal expansion of copper, and the pair of the SiO₂ films are covalent-bonded by dehydration condensation. These elements strongly bond together the first and the second semiconductor substrates 2 and 3.

In preparation for bonding, the first and the second semiconductor substrates 2 and 3 are processed, for example, by chemical mechanical polishing (CMP), so that the surfaces at which the first and the second metal pads 5 and 8 and the first and the second metal rings 16 and 17 are exposed, will be flat. In order to bond the first and the second semiconductor substrates 2 and 3, including the outer circumferences, it is desired to make flat surfaces even at the outer circumferences, on the first and the second semiconductor substrates 2 and 3. However, due to a film deposition process, a CMP process, or the like, in a process prior to the bonding process, it is difficult to make flat surfaces on the first and the second semiconductor substrates 2 and 3, including the outer circumferences thereof, and corners of the outer circumferences may be rounded. In bonding such first and second semiconductor substrates 2 and 3, the outer circumferential parts thereof may not be sufficiently bonded. Insufficient bonding at the outer circumferential parts of the first and the second semiconductor substrates 2 and 3 can cause separation between the first and the second semiconductor substrates 2 and 3, and moreover, defects may occur in the bonded substrate 4, in later processes.

In consideration of this, in the semiconductor device 1 (bonded substrate 4) of the embodiment, in order to enhance bonding properties between the outer circumferential parts of the first and the second semiconductor substrates 2 and 3, the first and the second metal rings 16 and 17 are respectively formed along the outer circumference of the approximately circular shape of the first and the second semiconductor substrates 2 and 3, and they are joined together, for example, by thermally expanding them. The flatness is not sufficient in each of surfaces at which only the first and the second insulating layers 7 and 10 are exposed, as in the outer circumferential part of a typical bonded substrate. Moreover, such first and second insulating layers 7 and 10 are not expected to be sufficiently joined together. On the other hand, the first and the second metal rings 16 and 17, which are thermally expanded and joined together, enhance bonding properties between the outer circumferential parts of the first and the second semiconductor substrates 2 and 3. The joined first and second metal rings 16 and 17 constitute a circumferential seal ring 18.

The first and the second metal rings 16 and 17 are formed along the outer circumferences of the first and the second semiconductor substrates 2 and 3, and they are preferably provided at positions inwardly separated from the outer circumferences of the first and the second semiconductor substrates 2 and 3, without exposing to the outer circumferential surfaces of the first and the second semiconductor substrates 2 and 3. FIG. 4 is an enlarged sectional view illustrating a part of the semiconductor device 1 in FIG. 1. FIG. 4 illustrates dummy first and second metal pads 5 and 8, and therefore, the first and the second wiring layers 6 and 9 are not illustrated. Nevertheless, at least one of the first metal pads 5 and at least one of the second metal pads 8 are respectively connected to the first and the second wiring layers 6 and 9, as illustrated in FIG. 1. As described above, FIG. 4 illustrate the first and the second metal rings 16 and 17. The first and the second metal rings 16 and 17 are formed by stacking a plurality of ring-shaped metal patterns in the direction in which the first and the second semiconductor substrates 2 and 3 face each other (Z direction). The first and the second metal rings 16 and 17 are respectively extended from the facing surfaces of the first and the second semiconductor substrates 2 and 3 (surfaces of the first and the second insulating layers 7 and 10) to the first and the second circuit regions 12 and 14 in the Z direction.

As illustrated in FIG. 4, the first and the second metal rings 16 and 17 are preferably provided at positions inwardly separated from the outer circumferences of the first and the second semiconductor substrates 2 and 3 by a predetermined distance “L”. This facilitates forming the first and the second metal rings 16 and 17 to the first and the second insulating layers 7 and 10. As described later in relation to the process of manufacturing the semiconductor device 1, the first and the second metal rings 16 and 17 are formed by exposing resist films formed on the first and the second insulating layers 7 and 10, developing to produce recesses, and filling the recesses with metal materials, such as of copper. During this process, if the outermost peripheries of the resist films, which are formed on the first and the second insulating layers 7 and 10 are also exposed, it is impossible to form the recesses to be used as filling-target parts for the first and the second metal rings 16 and 17. On the other hand, providing the first and the second metal rings 16 and 17 at the positions inwardly separated from the outer circumferences by the predetermined distance “L” enables reliably forming recesses to be used as filling-target parts for the first and the second metal rings 16 and 17. As a result, the first and the second metal rings 16 and 17 are suitably formed.

The widths of the first and the second metal rings 16 and 17, which are formed along the outer circumferences of the first and the second semiconductor substrates 2 and 3, may be different from each other. FIG. 5 is an enlarged sectional view illustrating the first and the second metal rings 16 and 17 of the semiconductor device 1 in FIG. 4. As illustrated in FIG. 5, assuming that the width of the second metal ring 17 is W2, the width W1 of the first metal ring 16 may be wider than the width W2. In one example, assuming that the width W2 of the second metal ring 17 is 1 μm or more and 10 μm or less, the width W1 of the first metal ring 16 is preferably set so as to satisfy the relation W1>W2 in the range of 3 μm or more and 30 μm or less. This improves positioning accuracy of the first and the second metal rings 16 and 17 and thereby enhances bonding properties therebetween. In this case, the first metal ring 16 having a wide width W1 may be formed by extending only the width W1 of the joined part, as illustrated in FIG. 5. The width W1 of the first metal ring 16 is widely set in FIG. 5, but instead, the width W2 of the second metal ring 17 may be widely set.

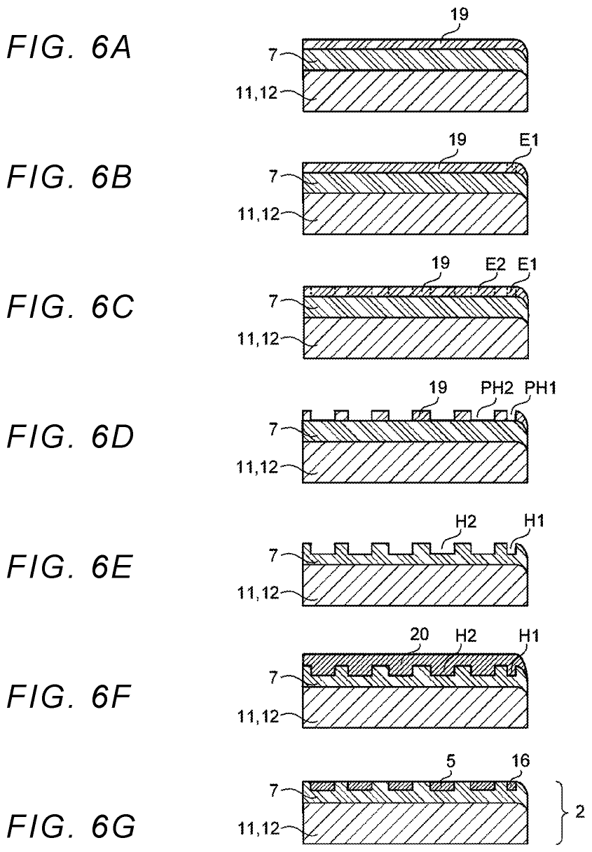

Next, a process of manufacturing the semiconductor device 1 of the embodiment will be described with reference to FIGS. 6A to 6G. FIGS. 6A to 6G illustrate only one of the first and the second semiconductor substrates 2 and 3. These are different from each other in having the first circuit, which includes peripheral circuits, e.g., a transistor such as a CMOS, and a passive element, or having the second circuit, which includes a pixel array or a memory cell array; however, the processes for forming the first and the second metal pads 5 and 8 are substantially the same, and the processes for forming the first and the second metal rings 16 and 17 are substantially the same. Thus, the first semiconductor substrate 2 having the first metal pads 5 and the first metal ring 16 and the second semiconductor substrate 3 having the second metal pads 8 and the second metal ring 17 are produced by processes similar to each other. Then, these first and second semiconductor substrates 2 and 3 are bonded, whereby the semiconductor device 1 is manufactured. FIGS. 6A to 6G illustrate a process of forming the first metal ring 16 of the first semiconductor substrate 2.

FIG. 6G illustrates dummy first metal pads 5, and therefore, the first wiring layer 6 is not illustrated. Nevertheless, at least one of the first metal pads 5 is connected to the first wiring layer 6, as illustrated in FIG. 1. FIG. 6G also illustrates a first metal ring 16 that is not connected to the first circuit region 12. This first metal ring 16 is formed by exposing the uppermost layer to be formed with the metal pads 5, and embedding a metal material therein. The shape of the first metal ring 16 (second metal ring 17) can be that illustrated in FIG. 4 or FIG. 6G. The first metal ring 16 (second metal ring 17) having two or more parts with different widths, as illustrated in FIG. 5, preferably has a structure of stacking a plurality of ring-shaped metal patterns in the Z direction. In this case, the ring-shaped metal patterns are formed by repeatedly performing a process of exposing a layer to be formed with the metal pads 5 (metal pads 8) and a plurality of wiring layers provided in the insulating layer 7 (insulating layer 10) so as to generate a ring-shaped pattern, and a process of embedding a metal material therein.

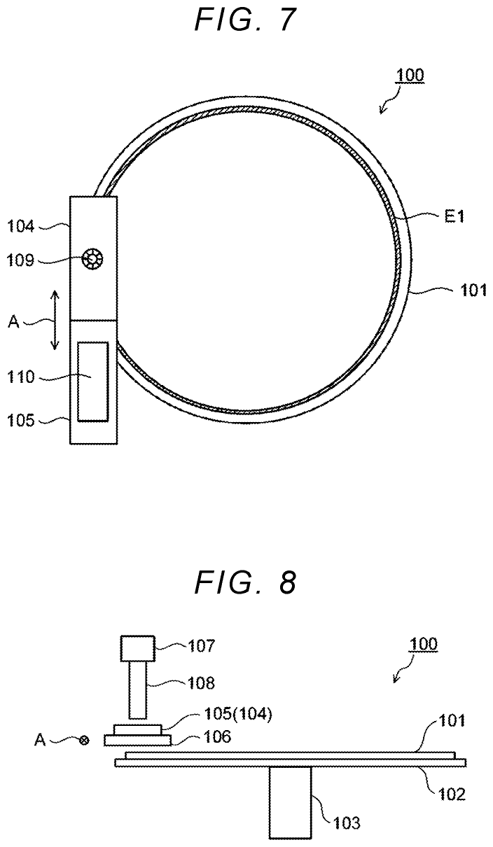

First, as illustrated in FIG. 6A, a resist film 19 is formed by using a photosensitive organic material or the like, on the first insulating layer 7 provided above the substrate part 11 of the first semiconductor substrate 2. As illustrated in FIG. 6B, a part to be formed with the first metal ring 16 is exposed, whereby an exposed region E1 for the first metal ring 16 is formed. The exposed region E1 is formed by using a circumference exposure apparatus 100, as illustrated in FIGS. 7 and 8. FIGS. 7 and 8 illustrate the circumference exposure apparatus 100 as a semiconductor manufacturing apparatus of the embodiment. FIG. 7 is a plane view of the circumference exposure apparatus 100, and FIG. 8 is a front view thereof.

As illustrated in FIGS. 7 and 8, the circumference exposure apparatus 100 includes a support 102 of a semiconductor substrate that is a target substrate 101, a rotary mechanism 103, a circumferential seal ring aperture (ring exposure aperture) 104, a circumference exposure aperture 105, a switching mechanism 106, a light source 107, and an optical unit 108. The rotary mechanism 103 turns the support 102 that supports the target substrate 101. The switching mechanism 106 switches between the circumferential seal ring aperture 104 and the circumference exposure aperture 105. The optical unit 108 includes a light guide member and a lens. The light guide member emits light that is emitted from the light source 107, to the semiconductor substrate, which is the target substrate 101. The light source 107 uses an ultraviolet (UV) light source, an extreme ultraviolet (EUV) light source, an excimer laser, or the like, in accordance with exposure.

The circumferential seal ring aperture 104 is used for forming the metal ring 16 and has a hole-shaped first opening pattern 109. The first opening pattern 109 is made so that the diameter of the opening pattern can be varied to change an exposure width in accordance with the width of the metal ring 16. The circumference exposure aperture 105 is used in a process of cutting an edge of the target substrate 101, independently of forming the metal ring 16. The circumference exposure aperture 105 has a slit-shaped second opening pattern 110 that enables exposing the outermost periphery of the target substrate 101 so that the resist at the circumference of the target substrate 101 will be removed. With the use of such a circumference exposure apparatus 100, independently of the process of cutting an edge of the target substrate 101, a process of exposing the target substrate 101 along the outer circumference thereof can be performed so as to generate a ring-shaped pattern, to form the exposed region E1 for the metal ring 16 at a position inwardly separated from the outer circumference by the predetermined distance “L”. In the case of using the circumference exposure apparatus 100 in a process of cutting an edge, the circumferential seal ring aperture 104 and the circumference exposure aperture 105 are moved in the arrow “A” direction so as to be switched by the switching mechanism 106.

Next, as illustrated in FIG. 6C, a part to be formed with the metal pad 5 is exposed, whereby an exposed region E2 for the metal pad 5 is formed. As illustrated in FIG. 6D, the exposed region E1 for the metal ring 16 and the exposed region E2 for the metal pad 5 are developed, whereby a ring-shaped pattern hole PH1 for the metal ring 16 and an approximately rectangular pattern hole PH2 for the metal pad 5 are formed in the resist film 19. Subsequently, as illustrated in FIG. 6E, the insulating layer 7 is etched by dry etching or wet etching, using the resist film 19 having the pattern holes PH1 and PH2, as a mask, to form a recess H1 for the metal ring 16 and a recess H2 for the metal pad 5. After the resist film 19 is removed, a metal material such as of copper or copper alloy is embedded in each of the recesses H1 and H2, and a metal film 20 is formed on the insulating layer 7, as illustrated in FIG. 6F. Thereafter, as illustrated in FIG. 6G, the metal film 20 is polished by CMP or the like, to remove unnecessary metal film 20, except for the metal materials embedded in the recesses H1 and H2.

The above-described manufacturing process is employed to manufacture the first semiconductor substrate 2 including the first metal ring 16, which is formed by embedding a metal material in the recess H1, and the first metal pad 5, which is formed by embedding a metal material in the recess H2, as illustrated in FIG. 6G. A process similar to this manufacturing process is employed to manufacture the second semiconductor substrate 3 including the second metal ring 17, which is formed by embedding a metal material in a recess H1, and the second metal pad 8, which is formed by embedding a metal material in a recess H2.

Next, the first semiconductor substrate 2, in which the surfaces of the first metal pad 5, the first insulating layer 7, and the first metal ring 16 are exposed, and the second semiconductor substrate 3, in which the surfaces of the second metal pad 8, the second insulating layer 10, and the second metal ring 17 are exposed, are bonded together. The bonding process is performed under existing well-known conditions. For example, the first and the second semiconductor substrates 2 and 3 are bonded together by mechanical pressure. Thus, the first and the second insulating layers 7 and 10 are joined and integrated. Then, the first and the second semiconductor substrates 2 and 3 are subjected to an anneal treatment, for example, at a temperature of 300 to 400° C. for approximately 1 hour. This causes the first and the second metal pads 5 and 8 to be joined together and also causes the first and the second metal rings 16 and 17 to be joined together, whereby the first and the second metal pads 5 and 8 are electrically connected and integrated.

In this manner, the bonded substrate 4 having the first and the second semiconductor substrates 2 and 3 being bonded together is manufactured. The first and the second metal rings 16 and 17 are joined and integrated to constitute the circumferential seal ring 18. The outer circumferential parts of the first and the second semiconductor substrates 2 and 3 are integrated by the circumferential seal ring 18, which prevents problems such as separation between the first and the second semiconductor substrates 2 and 3 and occurrence of defects in the bonded substrate 4 in later processes. As a result, it is possible to enhance manufacturing yield and quality of the semiconductor device 1 having the bonded substrate 4.

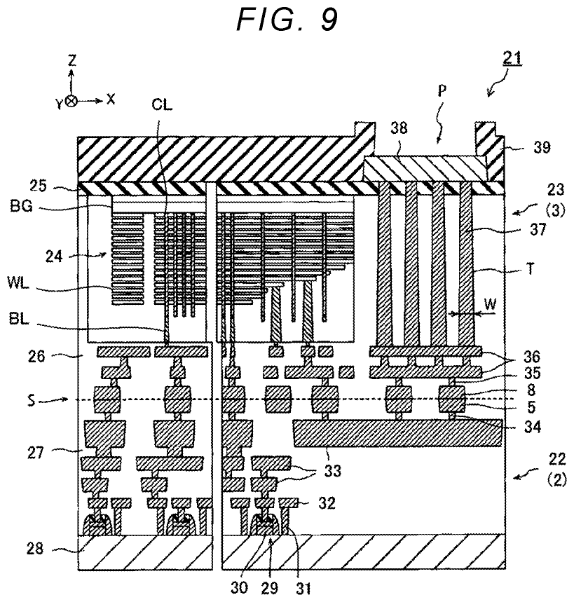

Next, an example of a semiconductor chip that is manufactured by using the semiconductor device 1 of the above-described embodiment will be described with reference to FIG. 9. A semiconductor chip 21 illustrated in FIG. 9 includes a control circuit chip 22 and an array chip 23. The control circuit chip 22 is composed of a part of the first semiconductor substrate 2 having the first circuit region 12. The array chip 23 is composed of a part of the second semiconductor substrate 3 having the second circuit region 14. Such a semiconductor chip 21 is manufactured by dicing the semiconductor device 1 of the embodiment, along the chip regions 15A and 15B, into pieces. The control circuit chip 22 and the array chip 23 are bonded together.

The array chip 23 includes a memory cell array 24 having a plurality of memory cells, an insulating film 25 above the memory cell array 24, and an interlayer insulating film 26 under the memory cell array 24. The control circuit chip 22 is provided under the array chip 23. The reference sign “S” shows a bonded surface of the array chip 23 and the control circuit chip 22. The control circuit chip 22 includes an interlayer insulating film 27 and a substrate 28 under the interlayer insulating film 27. The substrate 28 is a semiconductor substrate, such as a silicon substrate. Each of the insulating films 25, 26, and 27 is, for example, a silicon oxide film, a silicon nitride film, or a silicon oxynitride film, and each may have a structure in which one or more kinds of materials are mixed or stacked.

FIG. 9 illustrates an X direction and a Y direction being parallel to a surface of the substrate 28 and being perpendicular to each other and a Z direction being perpendicular to the surface of the substrate 28. Herein, a +Z direction is treated as an upward direction, and a −Z direction is treated as a downward direction. For example, the memory cell array 24 that functions as a part of the second circuit region 14 in the array chip 23 is positioned above the substrate 28, and the substrate 28 is positioned under the memory cell array 24. The −Z direction may or may not coincide with the direction of gravity.

The array chip 23 includes a plurality of word lines WL and a select gate line (not illustrated), as electrode layers in the memory cell array 24. FIG. 9 illustrates a stepped structure part of the memory cell array 24. A columnar part CL penetrates the word lines WL, and it is electrically connected to a source line BG at an end and is electrically connected to a bit line BL at the other end, whereby a memory cell is formed at an intersection of the columnar part CL and the word line WL.

The control circuit chip 22 includes a plurality of transistors 29 that function as a part of the first circuit region 12. Each transistor 29 includes a gate electrode 30 that is provided on the substrate 28 via a gate insulating film and also includes a source diffusion layer (not illustrated) and a drain diffusion layer (not illustrated) that are provided in the substrate 28. The control circuit chip 22 also includes a plurality of plugs 31, and wiring layers 32 and 33. The plug 31 is provided on the source diffusion layer or the drain diffusion layer of each transistor 29. The wiring layer 32 is provided on the plug 31 and has a plurality of wirings. The wiring layer 33 is provided above the wiring layer 32 and has a plurality of wirings. The control circuit chip 22 further includes a plurality of via plugs 34 provided on the wiring layer 33, and a plurality of metal pads 5 provided on the via plugs 34 in the insulating film 27. Such a control circuit chip 22 functions as a control circuit (logic circuit) that controls the array chip 23.

The array chip 23 includes, in the insulating film 26, a plurality of metal pads 8 that are provided on the metal pads 5, a plurality of via plugs 35 that are provided on the metal pads 8, and a wiring layer 36 that is provided on the via plugs 35 and has a plurality of wirings. Each of the word lines WL and the bit lines BL is electrically connected to a corresponding wiring in the wiring layer 36. The array chip 23 also includes a via plug 37 that is provided on the wiring layer 36 and in the insulating films 25 and 26, and a metal pad 38 that is provided on the insulating film 25 and on the via plug 37.

The metal pad 38 functions as an external connection pad of the semiconductor chip 21 illustrated in FIG. 9, and it can be connected to a mounting board or another device, via a bonding wire, a solder ball, a metal bump, or the like. The array chip 23 further includes a passivation film 39 formed on the insulating film 25 and on the metal pad 38. The passivation film 39 has an opening “P” that exposes the upper surface of the metal pad 38, and the opening “P” is used, for example, to connect a bonding wire to the metal pad 38.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first device; and
a second device bonded to the first device,
the first device comprising:
a plurality of first metal pads provided above a semiconductor substrate with an approximately circular shape;
a first circuit coupled to at least one of the plurality of the first metal pads; and
a first metal ring provided along an outer circumference of the semiconductor substrate to surround the first circuit,
the second device comprising:
a plurality of second metal pads joined to the plurality of the first metal pads, respectively;
a second circuit coupled to at least one of the plurality of the second metal pads; and
a second metal ring joined to the first metal ring.

2. The semiconductor device according to claim 1, wherein the second metal ring surrounds the second circuit.

3. The semiconductor device according to claim 1, wherein the first device includes a plurality of first chip regions, each of the first chip regions having the plurality of the first metal pads and the first circuit,
the second device includes a plurality of second chip regions, each of the second chip regions having the plurality of the second metal pads and the second circuit,
the plurality of the first chip regions and the plurality of the second chip regions are bonded by the first metal pads and the second metal pads, and
the first metal ring and the second metal ring surround the plurality of the first chip regions and the plurality of the second chip regions.

4. The semiconductor device according to claim 1, wherein the first metal ring and the second metal ring constitute a circumferential seal ring.

5. The semiconductor device according to claim 1, wherein the first metal ring is provided at a position inwardly separated from the outer circumference of the semiconductor substrate.

6. The semiconductor device according to claim 1, wherein at least one of the first metal ring and the second metal ring has a structure of stacking a plurality of ring-shaped metal patterns in a direction crossing a substrate surface of the semiconductor substrate.

7. The semiconductor device according to claim 1, wherein the first device and the second device respectively have a first insulating layer part and a second insulating layer part at respective bonded surfaces of the first device and the second device, the first metal ring is embedded in a recess that is provided in the first insulating layer part, and the second metal ring is embedded in a recess that is provided in the second insulating layer part.

8. The semiconductor device according to claim 1, wherein the plurality of the first metal pads and the plurality of the second metal pads each contain copper.

9. The semiconductor device according to claim 1, wherein the first metal ring and the second metal ring each contain copper.

10. The semiconductor device according to claim 1, wherein one of the first circuit and the second circuit constitutes a memory cell array including a plurality of memory cells, and the other one of the first circuit and the second circuit constitutes a plurality of transistors configured to control the memory cell array.

11. A semiconductor device comprising:
a first device; and
a second device bonded to the first device,
the first device comprising:
a plurality of first chip regions, each of the first chip regions having a plurality of first metal pads and a first circuit coupled to at least one of the plurality of the first metal pads; and
a first metal ring provided along an outer circumference of a substrate to surround the plurality of the first chip regions,
the second device comprising:
a plurality of second chip regions, each of the second chip regions having a plurality of second metal pads and a second circuit coupled to at least one of the plurality of the second metal pads, the second metal pads joined to the plurality of the first metal pads, respectively; and
a second metal ring joined to the first metal ring,
the first metal ring and the second metal ring, which are joined together, constitute a circumferential seal ring for the plurality of the first chip regions and the plurality of the second chip regions.

12. The semiconductor device according to claim 11, wherein the first metal ring is provided at a position inwardly separated from the outer circumference of the substrate.

13. The semiconductor device according to claim 11, wherein at least one of the first metal ring and the second metal ring has a structure of stacking a plurality of ring-shaped metal patterns in a direction crossing a substrate surface of the substrate.

14. The semiconductor device according to claim 11, wherein the first device and the second device respectively have a first insulating layer part and a second insulating layer part at respective bonded surfaces of the first device and the second device, the first metal ring is embedded in a recess that is provided in the first insulating layer part, and the second metal ring is embedded in a recess that is provided in the second insulating layer part.

15. The semiconductor device according to claim 11, wherein the plurality of the first metal pads and the plurality of the second metal pads each contain copper.

16. The semiconductor device according to claim 11, wherein the first metal ring and the second metal ring each contain copper.

17. The semiconductor device according to claim 11, wherein one of the first circuit and the second circuit constitutes a memory cell array including a plurality of memory cells, and the other one of the first circuit and the second circuit constitutes a plurality of transistors configured to control the memory cell array.

18. A semiconductor manufacturing apparatus comprising:
a ring exposure aperture having a hole-shaped first opening pattern;
a circumference exposure aperture having a slit-shaped second opening pattern;
a switching mechanism configured to switch between the ring exposure aperture and the circumference exposure aperture; and
a light source configured to emit light to a target substrate via the first opening pattern or the second opening pattern.

19. The semiconductor manufacturing apparatus according to claim 18, wherein the ring exposure aperture is configured so that a diameter of the first opening pattern is variable.

20. The semiconductor manufacturing apparatus according to claim 18, further comprising:
a support configured to support the target substrate; and
a rotary mechanism configured to turn the support.
